(19) United States
(12) Patent Application Publication
(10) Pub. No.: US 2002/0019967 A1
(43) Pub. Date: Feb. 14, 2002

(54) Communication system, transmitter, method of protection against transmission errors

(76) Inventor: Jean-Luc Bonifas, Paris (FR)

Correspondence Address: U.S. Philips Corporation, 580 White Plains Road, Tarrytown, NY, 10591, US

(21) Appl. No.: 09/900,337

(22) Filed: Jul. 6, 2001

(30) Foreign Application Priority Data
Jul. 11, 2000 (FR) 0009049

(51) Int. Cl. H03M 13/03

(52) U.S. Cl. 714/786

(57) ABSTRACT

The invention relates to a method of protecting against transmission errors for frames of digital primary data comprising primary data of different priorities, so as to supply via a communication channel data frames which are protected against the transmission errors. A priority level associated with the primary data is determined, on the one hand for informing the protection step carrying out the protection against the errors thereof and on the other hand for taking a decision on the necessity of protecting said primary data. The protection step against the errors, of the FEC type, renders it possible to deliver the protected data on the basis of said primary data through the addition of a quantity of redundancy information to each type of primary data, which quantity depends both on their priority level and on a value indicative of the quality of the communication channel.

The invention relates to a method of protection against transmission errors for frames of primary digital data comprising primary data of different priorities so as to supply over a communication channel data frames which are protected against transmission errors.

It also relates to a communication system comprising a transmitter for transmitting frames of primary digital data to a receiver through a communication channel, said transmitter being provided with means adapted so as to implement the method mentioned above.

It has numerous applications in communication systems for multimedia data in general, as is the case in particular in applications of the videophone type over mobile or wired networks.

The European patent published under no. 0 680 157 A1 describes a method and a system for controlling the protection against errors of data transmitted by a transmitter to a receiver via a transmission path. This method carries out a protection of the data to be transmitted through an optimized utilization of the available passband in the transmission path. To achieve this, the data to be transmitted are classified into different levels of importance in a first time period, and in a second time period are encoded in accordance with an algorithm with the object of adding redundancy data thereto. This addition of redundancy data takes into account the level of importance of the data to be transmitted so as to vary the degree of protection.

The method of protection against transmission errors carried out according to the prior art document has a number of disadvantages.

First of all, the protective power is defined in advance, i.e. this method does not take into account any changes in the transmission quality which may put into question the protective power for the data to be transmitted. This method accordingly suffers from a lack of adaptation of the protection of the data to the fluctuating transmission conditions, which under these conditions results in a bad occupation of the passband of the transmission path on the one hand, but on the other hand also in a bad protection of the transmitted data.

Furthermore, the method described implies the implementation of a rigid architecture which renders it necessary to define in advance the number of levels of importance of the data to be protected. This rigidity of the architecture has the result that a procedure for data processing is carried out for each of the levels of importance. There are accordingly as many processing procedures as there are levels of importance, which leads to an expensive solution of low flexibility.

The invention has for its object to remedy these disadvantages to a high degree by proposing a communication system, a transmitter, as well as a method for the purpose of protecting primary data frames transmitted over a communication channel in a selective manner which is more reliable and less expensive than that described in the prior art document.

To achieve this object, the present invention is characterized in that the protection method comprises attribution means for attributing a priority level to each of the frames of primary data, and protection means of the FEC type against transmission errors for adding redundancy data packets to the frames of primary data for which a protection is sought, the quantity of the redundancy data being a function of the level of priority of the primary frame under consideration and of the error rate of the communication channel, said protection means delivering said frames of protected data over the communication channel.

The protection method according to the invention comprises a generic sequence of process steps leading to the delivery of data which are protected against transmission errors on a communication channel. This sequence of process steps is applied to all primary data which are to be protected against the errors. In a first time period, wherein the primary data are presumed to be of various types, a detection of their types is carried out. A priority relating to the primary data is subsequently determined by means of a correspondence table, on the one hand for informing the protection step carrying out the protection against the errors thereof, and on the other hand for taking a decision on the possibility or necessity of protecting said primary data. In fact, the transmission error protection step consists in an addition of redundancy information to the primary data, so that it is possible not to protect the data of a certain type if it is judged that this would lead to a too great increase in the quantity of data transmitted over the communication channel, or if it is judged that the priority of the data is sufficiently low for not providing them with a protection against the errors. The error protection step, of the FEC (Forward Error Correction) type, renders it possible to supply said protected data on the basis of said primary data, of their associated priorities, and of a value representing the quality of the communication channel. This FEC type protection step, for example in accordance with the standard IETF RFC 2733 in the context of a packet transmission RTP (Real-time Transport Protocol), renders it possible to add to each type of primary data a quantity of redundancy information which takes into account their priority, while at the same time said value represents the quality of the communication channel. In fact, the quantity of redundancy information is greater in proportion as the priority of the primary data is higher and as the quality of the communication channel is worse. The method described above is thus generic, because a single process sequence is carried out irrespective of the type of primary data under treatment, is less expensive because process sequences are not multiplied as a function of the different types of primary data, and is flexible because the number of redundancy data added to the primary data is adapted to the current quality of the communication channel.

The invention also relates to a transmitter forming part of a system of communication, for example of the radiotelephony type, whose operation can benefit from the protection possibilities against errors as described above. The invention in fact provides a generic set of process steps for said primary data so as to transmit to a receiver data which are protected against transmission errors. The transmitter thus controls the redundancy level of the data sent in a manner adapted to the priority level of the data and to the quality of the transmission channel, while safeguarding an optimum compromise between the occupation of the passband of the transmission channel and the level of protection against the errors.

These aspects of the invention as well as other, more detailed aspects will become clearer from the following description given with reference to the annexed drawings, all by way of example to which the invention is not limited. In the drawing:

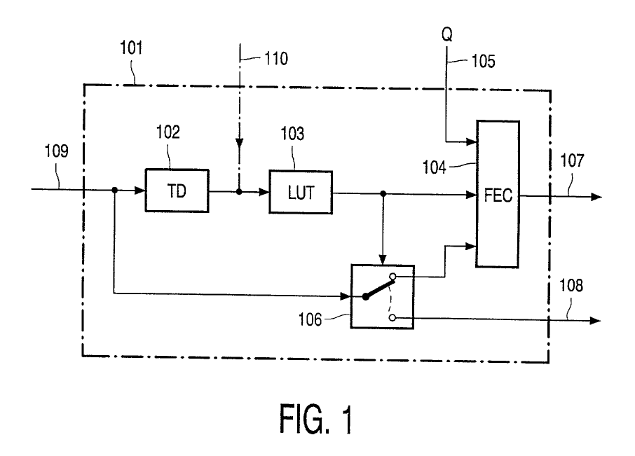

FIG. 1 is a block diagram representing the sequence of the different operations according to the invention, and

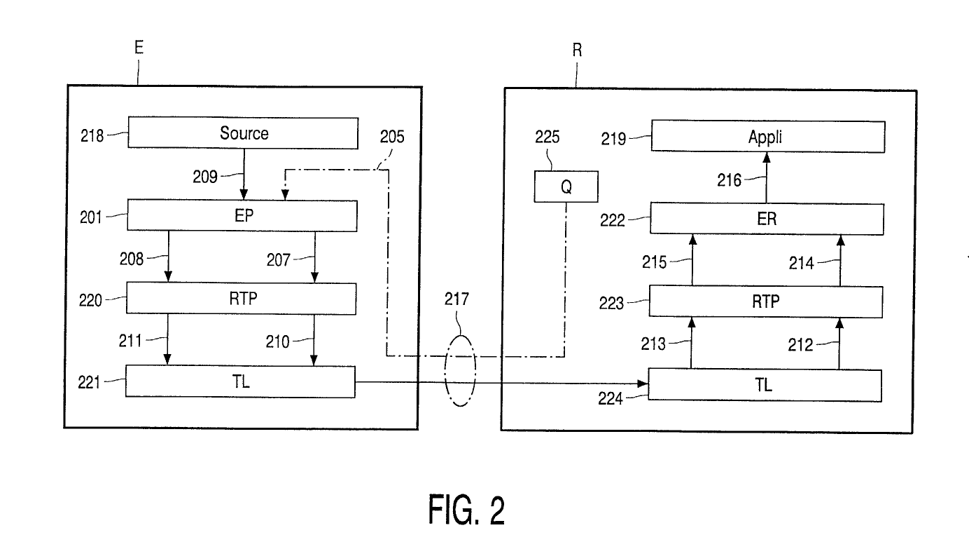

FIG. 2 is a diagram representing a communication system comprising a transmitter according to the invention.

FIG. 1 diagrammatically shows the individual steps leading to the protection of the primary data sent by a transmitter over a communication channel. The sequence 101 of individual steps renders it possible to supply data 107 protected against transmission errors and/or data 108 not subjected to any protection treatment against the errors, starting from primary data 109. The primary data 109 correspond to frames of digital data issued, for example, by an audio/video encoder, or more generally issued by a source of digital multimedia data. These primary data frames are issued, for example, by an audio/video encoder of the MPEG-1/MPEG-2/MPEG-4 or H.263 family, or from applications using standards H.324 or H.323. This type of data has the characteristic that it comprises different types of data which can be identified and be synchronized during decoding. In the context of the invention, these different types of data are interpreted and translated at the priority level. In fact, there is a certain hierarchy for such data which renders it possible to describe the information content delivered by said source. For example, if the primary data 109 relate to video data encoded in accordance with the MPEG-2 or the MPEG-4 standard, the data relating to Video Object (VO), Video Object Layer (VOL), Group of Video plane (GOV), Video Object Plane (VOP) and Video Packet (VP) define an interlaced hierarchical structure of decreasing priority in which it is preferable to protect the data relating to images against errors, i.e. those data which have the highest priority. A detection step 102 is provided for this purpose for detecting the type of data or primary data frames 109 so as to assign to them a priority level. This detection is based on the analysis of the coding syntax of the primary data 109, referring in particular to the keywords of the syntax contained in the various headers. In another modification of the invention, it is possible not to carry out a detection of the type of data 109, this type information being directly provided by external elements such as the encoder or the source which supplies the data 109. This alternative route is referenced 110. Once the type of the primary data is known, a correspondence is established between said type information and a priority level in step 103. This step, explained in more detail below, consists in the implementation of a correspondence table in which a user has previously established a correspondence between each type of data and a priority level. The number of correspondences is not limited by any constraint whatsoever, so that this method may be adapted to different data sources containing data types in different numbers from this level in the process onward. It suffices for this purpose to provide a correspondence table comprising a number of correspondences which is sufficiently great, which means that they may not all be used if the primary data comprise a small number of types. The step 103 thus supplies a value relating to the priority of the primary data or data frames 109. Depending on the value for this priority level, the data 109 are effectively protected against transmission errors, or alternatively are not subjected to any supplementary treatment. The element 106 is charged with making this choice, determining the path of the primary data 109 through the process sequence 101. It may in fact be decided not to protect the primary data of low priority, which means that either data of low importance are present which do not justify protection, or data are present which can be reconstructed after transmission even if they should have numerous errors. In these cases, the data 109 are not protected against the errors so as not to burden the passband of the communication channel through which the primary data are sent to an unnecessarily high degree. In the opposite case, i.e. in which the priority of the primary data is judged to be sufficiently high, the element 106 switches the data 109 towards the error protection step 104. This protection step has for its object to add redundancy data to the primary data 109 so as to enable a reconstruction of these primary data after transmission, also if they have been subject to numerous errors during their transmission. The step 104 renders it possible to deliver data 107 protected against transmission errors by carrying into practice an algorithm of the FEC type in a specific and innovative way. The invention for this purpose provides a selective protection for the primary data in the sense that the quantity of redundancy, for example expressed as a percentage of the volume of bytes of primary data to which this redundancy addition is applied, takes into account the priority of the primary data. In other words, the redundancy percentage added to the primary data will be greater in proportion as the priority level thereof is higher. This aspect of the invention will be explained in more detail below. In this way, it is possible to guarantee an optimum protection of the important data while at the same time no redundancy data added to primary data of low priority level are transmitted over the communication channel, which means that the communication channel is not unnecessarily burdened. The protection step 104 receives in addition to the data 109 and the value indicating their priority level a value 105 representing the quality Q of the transmission channel. This value is a function, for example, of the error rate of the communication channel estimated from the number of data frames lost in this channel during a certain time period, which estimation is made at the level of a remote device, and the result of this estimation step is sent to the transmitter. In this manner the quantity of redundancy added to the primary data is modulated by this quality value of the communication channel: the quantity of redundancy added to the primary data is higher in proportion as this quality value indicates a higher error rate. The primary data are thus not protected on the basis of an arbitrary value of the quality of the communication channel, but instead on the basis of a quality value representing the real characteristics of this channel: the degree of protection is perfectly adapted to the transmission conditions of the data.

The protection against transmission errors is thus safeguarded by a dual strategy which is carried out jointly so as to be able to quantify the redundancy data to be added to the primary data, which strategy comprises:

an evaluation of a first quantity of redundancy data made on the basis of the priority level of the primary data, which first quantity is higher in proportion as the priority level is higher,

a modulation of this first quantity of redundancy data carried out on the basis of a value representing the reliability and the quality of the communication channel, which modulation takes the form of an augmentation of the quantity of redundancy data which is greater in proportion as the communication channel is less reliable or as the error rate of the transmission is higher, which augmentation of the redundancy data is obviously limited by the maximum passband of the transmission channel.

FIG. 2 shows a communication system comprising a transmitter according to the invention. This communication system comprises an emitter E which communicates via a communication channel 217 of a wired or radio wave type with a receiver R which receives the protected data so as to utilize them in, for example, multimedia applications. This communication system corresponds, for example, to an application such as video streaming, video on demand or video telephony, and using the H.323 standard (using the transmission protocol RTP) for the transmission of video on the Internet, or the H.324 standard (using the transmission protocol in accordance with the H.223 standard) relating to an application of the video telephone type, or an application of the GSM type, or an application in accordance with the Bluetooth standard.

The transmitter E comprises a source 218 of primary digital data or data frames 209 issued, for example, by a server or by an audio/video encoder and sent to the module 201 for protection against errors. Parallel to these primary data, the module 201 receives a signal 205 indicative of the quality of the transmission channel 217. For this purpose, it is possible to use the RTCP (RTP Control Protocol) protocol defined jointly with the RTP protocol in accordance with the standard RCF 1889 IETF, for using the statistics which it renders possible to deliver on the quality of the communication, such as the number of data packets lost since the last packet RTCP received at the level of the receiver R. This estimation of the quality of the communication channel is carried out by the block 225, which transmits the result of its estimation to the transmitter via the signal 205. Any other means, however, for example a proprietary means, may be used for delivering an information 205 indicative of the quality of the transmission channel. The module 201, as described with reference to FIG. 1, supplies either data without protection 208 or data 207 protected through the addition of redundancy data on the basis of the primary data 209, the degree of protection of the primary data depending both on their priority level and on the quality of the transmission 217. The following description will now be given on the basis of an application in accordance with the RTP protocol, but the invention is not limited to this.

In a preferred embodiment, a communication system is considered which can carry out the transmission of encoded data in accordance with the MPEG-4 standard between a transmitter according to the invention and a receiver through a communication channel which uses the Bluetooth standard. In this case, and as desired by the user, the video data of the GOV (Group Of Video Object Plane) type, the motion vector data MV, and the TEXTURE data constitute three types of data of decreasing priority p( ): p(GOV)>p(MV)>p(TEXTURE). A high priority level may in fact be given to the GOV type, a medium priority level to the MV type, and a low priority level to the TEXTURE type, considering that the data of this latter type are not indispensable to the application and that errors or losses of these data are detrimental to a low degree only. Three degrees of protection for the primary data are thus defined by the module 201 for a certain quality Q1 of the communication channel:

a) addition of 100% of redundancy data to the GOV type data,

b) addition of 50% of redundancy data to the MV type data,

c) addition of 5% of redundancy data to the TEXTURE type data.

For a transmission quality Q2 over the communication channel, worse than in the preceding example, i.e. Q2<Q1, the three degrees of protection for the primary data are now defined by:

a) addition of 200% of redundancy data to the GOV type data,

b) addition of 60% of redundancy data to the MV type data,

c) no addition of redundancy data to the TEXTURE type data.

This example is a perfect illustration of the dual strategy described above for quantifying the redundancy data to be added to the primary data, in the sense that the volume of redundancy data depends not only on the priority of the data but also on the quality of the communication channel: here, in the case in which Q=Q2, and in comparison with the case in which Q=Q1, the redundancy data are mainly superimposed on the GOV data, as against the data of the MV type, of which the redundancy quantity is increased only little, on the one hand because they do not have a high priority level and on the other hand so as not to saturate the communication channel. As for the data of the TEXTURE type, no redundancy data are added at all if Q=Q2, because their priority level is the lowest and because all protection efforts are aimed at the GOV type data. The data of the TEXTURE type are sent over the communication channel without protection against errors, which transmission may be achieved by the FEC protection module (without the addition of redundancy data) or by a simple switching of the primary data over said communication channel.

In a manner similar to that for the GOV, MV, and TEXTURE data, other data having different priority levels may be subjected to a selective protection before being sent over the communication channel. Within the MPEG-4 standard, or more generally within the MPEG standards for video compression, it is in fact sensible to provide a selective protection to data belonging to different image types I, P, and B. The I type is designed for INTRA images for which no movement compensation is carried out. The I type images serve as a reference for temporal prediction of other images in the sequence, although they have a high priority level associated with them. The P type is designed for images for which a temporal prediction has been made so as to profit from the temporal redundancy which exists between two consecutive images in a video sequence, and thus to augment the video compression rate. The P type images are coded with reference to a reference image of the I type. The B type is designed for images for which a double temporal prediction has been made so as to obtain a maximum compression rate for these images. They are given a low priority level in view of the fact that these images, should they become degraded during their transmission, may be recovered through interpolation from the I and P type images.

Three protection levels in dependence on the priority levels of the data of the types I, P, and B can thus be provided in the context of a selective FEC type protection against transmission errors:

a) major addition of redundancy data to the data defining images of the I type, the protection against the errors being effected through concatenation of a large number of redundancy data (FEC packets) with the data defining the I type images. Advantageously, it may also be envisaged that a FEC packet protecting important data against errors contains only a limited number of FEC packets combined in its mask;

b) addition of a small amount of redundancy data to data defining images of the P type, which addition of redundancy data is achieved through concatenation of a small number of FEC packets with the primary data which define the P type images;

c) no addition of redundancy data to the primary data defining the B type images.

These data analyzed and/or processed by 201 are then sent to the module 220 which has as its function to format them in accordance with the RTP protocol, in particular by adding a header RTP specific to the FEC protection to each of the data frames so as to synchronize the primary data and the corresponding redundancy data at the receiver end. The module 220 thus sends formatted data frames 210 and 211 in accordance with the RTP protocol on the basis of the data 207 and 208, respectively. Each of the data frames 210 and 211 is transmitted over the communication channel 217 via the transport layer 221.

Advantageously, the addition of redundancy data to the primary data to be transmitted over a communication channel may be limited by the characteristics of this channel. A communication channel in fact always has a limited passband, so that the addition of redundancy data (FEC packets) must be such that the data rate of the data protected against errors must continuously be below or equal to that of the communication channel, even if fluctuations occur in the passband of this channel. The data rate of the data protected against errors may be seen as the sum of the data rate of the primary data and the data rate of the redundancy data. If the error rate of the transmission over the channel 217 is known, a data rate for the redundancy data to be associated with the primary data is determined so as to achieve a maximum correction of the detected errors at the receiving end (maximum recovery rate), which determination can be made experimentally or by means of tables based on transmission error rate parameters, the redundancy data rate being attuned to the desired recovery rate. The redundancy data rate thus determined is kept constant in time as long as the transmission error rate does not change, but if it does, a new determination is made in dynamic fashion for taking into account the real conditions of the communication channel.

According to a first strategy, when the maximum passband of the communication channel becomes smaller, which is the case, for example, if the communication network is saturated, the data rate 209 of the primary data issuing from 218 is automatically adjusted by a controller situated at the transmitter level such that the sum of the data rates of the primary data and of the redundancy data is always equal to the said maximum passband of the communication channel. This adjustment of the data rate 209 by said controller in the case in which the source 218 generates a compressed video signal in accordance with the MPEG-4 standard is obtained through augmentation of the quantifying steps of the DCT (Discrete Cosine Transform) blocks. Inversely, if the maximum passband of the communication channel widens, said controller will augment the data rate 209 by reducing the quantifying steps of the DCT blocks so as to optimize and maximize the filling of the passband of the communication channel.

According to a second strategy for achieving that the sum of the data rates of the primary data and of the redundancy data always remain equal to the maximum passband of the communication channel, said controller puts into operation a time scaling technique. This technique consists in that the controller indicates to the source 218 which primary data cannot be sent over the communication channel. If the maximum passband of the communication channel is reduced or the transmission error rate increases, i.e. if the data rate of the primary data 209 is to be reduced, the primary data of low priority are not transmitted over the communication channel.

According to a third strategy for achieving that the sum of the data rates of the primary data and of the redundancy data always remain equal to the maximum passband of the communication channel, said controller puts into operation a selection technique among a set of primary data flows having different data rates. In this case the source 218 no longer provides one, but several synchronous data flows 209 with different data rates, for example a first flow with data rate D1 and a second flow with data rate D2, with D1<D2, which flows originate from one and the same video sequence and are encoded in parallel with two separate video encoders, or alternatively pre-encoded and subsequently stored on a storage medium (for example, a hard disk). If now the data rate of the primary data is to be reduced, the controller selects a primary data flow 209 of a lower data rate, for example by switching from data rate D2 to D1. Inversely, the controller will select a primary data flow 209 of higher data rate if the rate of the primary data can be increased, i.e. changing from data rate D1 to D2.

At the receiver end R, the data frames received via the transport layer 224 are divided into two categories: the data frames 213 which have not been subjected to any error protection and the data frames 212 which have been subjected to a FEC type error protection. Sent to the module 223, the data frames 212 and 213 are analyzed so as to suppress their syntax associated with the RTP protocol, which syntax serves to synchronize the various data frames received. The module 223 thus supplies to the module 222 data frames 215 without protection and data frames 214 which contain both primary data and redundancy data. At this level, the frames 215 and 214 correspond to the frames 208 and 207, respectively, except in as far as errors have occurred during the transmission over the channel 217, which is why the module 222 has for its object to reconstruct the data affected by errors:

either on the basis of the single, non-protected data 215 with a content of low priority level, mainly on the basis of an interpolation with non-corrupted data previously received,

or through the use of the redundancy data associated with the data frames 214 through the application of a FEC type algorithm described in the standard RFC 2733.

It should be noted that the success of this reconstruction of the transmitted primary data will be more probable in proportion as the ratio of the number of errors present to the quantity of redundancy data is lower.

The data 216 thus reconstructed and freed from errors are now sent to an application 219, for example for being decoded and displayed on a screen if they are data of the video type.

The individual steps according to the invention which render it possible to deliver frames of protected data may be implemented at the transmitter level in various ways, in particular through the use of a signal processor which carries out a set of instructions corresponding to the processes 102/106/104 applied to the primary data frames, and through the use of a memory whose contents render it possible to establish the type/priority correspondence of step 103.

A communication system, a transmitter, as well as a method of protecting data transmitted over a communication channel subject to errors against these errors in a selective manner have thus been described and illustrated. Obviously, numerous modifications may be made in relation to the embodiments described without departing from the scope of the invention.

1. A transmitter comprising means for generating frames of primary digital data and designed for transmitting said frames of primary digital data protected against errors to a receiver via a communication channel, characterized in that the protection method comprises attribution means for attributing a priority level to each of the frames of primary data, and protection means of the FEC type against transmission errors for adding redundancy data packets to the frames of primary data for which a protection is sought, the quantity of the redundancy data being a function of the level of priority of the primary frame under consideration and of the error rate of the communication channel, said protection means delivering said frames of protected data over the communication channel.

2. A transmitter as claimed in claim 1, characterized in that the packets of redundancy data associated with the frames of primary data are more numerous in proportion as the priority level of said frames of primary data is higher and as the error rate of the channel is higher.

3. A transmitter as claimed in claim 2, characterized in that the assignment of a level of priority to each of the frames of primary data is made in two stages, first by means of an identification of the type of data contained in each of the frames of primary data, and subsequently by relating said type of data to a priority level by means of a correspondence table stored in a memory.

4. A transmitter as claimed in claim 3, characterized in that it comprises control means for ensuring that the data rate of the frames of protected primary digital data sent over the communication channel does not exceed the maximum passband of said communication channel by acting on said means for generating frames of primary digital data.

5. A transmitter as claimed in claim 4, characterized in that said means for generating frames of primary digital data deliver a single flow of primary data of which the data rate is controlled by said control means.

6. A transmitter as claimed in claim 5, characterized in that said control means prevent the transmission of certain frames of primary data, especially of those whose priority level is low.

7. A transmitter as claimed in claim 6, characterized in that said means for generating frames of primary digital data deliver several synchronous primary data flows each having a different data rate, said control means selecting from these different flows those frames of primary data which are to be protected against transmission errors.

8. A telephone device comprising a transmitter as claimed in claim 1.

9. A method of transmitting data, comprising a step of generating frames of primary digital data for the purpose of transmitting said frames of primary digital data protected against errors to a receiver via a communication channel, characterized in that the method further comprises:
a step of attributing a level of priority to each of the frames of primary data,
a protection step of the FEC type against transmission errors, adding packets of redundancy data to those frames of primary data for which a protection is envisaged, the quantity of the redundancy data being a function of the level of priority of the primary frame under consideration and of the error rate of the communication channel,
said protection step supplying said data frames protected to the communication channel.

10. A method of transmitting data as claimed in claim 9, characterized in that the packets of redundancy data associated with the frames of primary data are more numerous in proportion as the priority level of said frames of primary data is higher and as the error rate of the channel is higher.

11. A method of transmitting data as claimed in claim 10, characterized in that the assignment of a level of priority to each of the frames of primary data is made by means of a first step of identifying the type of data contained in each of the frames of primary data, and subsequently by means of a step which relates said type of data to a priority level.

12. A method of transmitting data as claimed in claim 11, characterized in that it comprises a control step for ensuring that the data rate of the frames of protected primary digital data sent over the communication channel does not exceed the maximum passband of said communication channel, by acting on said means for generating frames of primary digital data.

13. A method of transmitting data as claimed in claim 12, characterized in that said step of generating frames of primary digital data enables the delivery of a single flow of primary data of which the data rate is controlled by said control means.

14. A method of transmitting data as claimed in claim 13, characterized in that said control step prevents the transmission of certain frames of primary data, especially of those whose priority level is low.

15. A method of transmitting data as claimed in claim 14, characterized in that that said step of generating frames of primary digital data enables the delivery of several synchronous primary data flows each having a different data rate, said control step selecting from these different flows those frames of primary data which are to be protected against transmission errors.

16. A computer program product for a transmitter, comprising means for generating frames of primary digital data for the transmission of these primary digital data protected against transmission errors to a receiver via a communication channel, said computer program comprising a series of instructions in program code for carrying out the steps of the method as claimed in claims 9 to 15 when said program is executed by a signal processor incorporated in said transmitter.
